(19) United States
(12) Patent Application Publication
(10) Pub. No.: US 2016/0289064 A1
(43) Pub. Date: Oct. 6, 2016

(54) Thin Film Encapsulation of Electrodes

(71) Applicant: Agency for Science, Technology and Research, Connexis, Singapore (SG)

(72) Inventors: Jae-Wung Lee, Singapore (SG); Jaibir Sharma, Singapore (SG); Navab Singh, Singapore (SG)

(21) Appl. No.: 15/104,182

(22) PCT Filed: Dec. 16, 2014
(86) PCT No.: PCT/SG2014/000599

§ 371 Date: Jun. 13, 2016

(30) Foreign Application Priority Data
Dec. 19, 2013 (SG) 201309424-8

(51) Int. Cl. B81B 7/00; B81C 1/00

(52) U.S. Cl. CPC B81B 7/0058; B81C 1/00825; B81C 2203/0172; B81C 2203/0154

(57) ABSTRACT

A method of fabricating encapsulated microelectromechanical system (MEMS) devices, comprising: providing a substrate having one or more MEMS devices formed thereon; depositing a sacrificial layer over the substrate and the one or more MEMS devices; patterning the sacrificial layer to define one or more cavities in the sacrificial layer and around the one or more MEMS devices; forming a cap layer over the sacrificial layer and the one or more cavities, the cap layer having one or more etch holes defined therein; removing the sacrificial layer by etching the sacrificial layer at least through the one or more etch holes; and depositing a sealing layer over the cap layer and the one or more etch holes to encapsulate the one or more MEMS devices, the substrate, and the cap layer.

### PRIORITY CLAIM

The present application claims priority to Singapore Patent Application No. 201309424-8, filed 19 Dec., 2013.

### FIELD OF THE INVENTION

The present invention relates to the field of electrode fabrication. In particular, it relates to arrangements for Thin Film Encapsulation (TFE) of electrodes.

### BACKGROUND

Microelectromechanical system (MEMS) devices are small integrated devices that combine electrical and mechanical components. The demand for MEMS devices is increasing as more MEMS devices are integrated into sensors, optics, and radiofrequency (RF) devices.

MEMS devices are typically sub-micron in size, with any number of MEMS devices present on an integrated circuit board. MEMS devices require highly controlled environments for reliability. Presently, MEMS packaging techniques are used to protect the fragile hanging structures of MEMS devices from the harsh environment. However, conventional MEMS packing techniques comprise bonding of wafers, which requires a large area during dicing. Moreover, these techniques suffer from low yield and produce MEMS packages with a large thickness. It is apparent that present MEMS packaging techniques are inefficient techniques for producing encapsulated MEMS devices.

Accordingly, what is needed is a robust and efficient MEMS packaging technique for fabricating electrodes. Furthermore, other desirable features and characteristics will become apparent from the subsequent detailed description and the appended claims, taken in conjunction with the accompanying drawings and this background of the disclosure.

### SUMMARY OF THE INVENTION

In a first aspect of the present invention, a method of fabricating encapsulated microelectromechanical system (MEMS) devices is disclosed, the method including: providing a substrate having one or more MEMS devices formed thereon, depositing a sacrificial layer over the substrate and the one or more MEMS devices, patterning the sacrificial layer to define one or more cavities in the sacrificial layer and around the one or more MEMS devices, forming a cap layer over the sacrificial layer and the one or more cavities, the cap layer having one or more etch holes defined therein, removing the sacrificial layer by etching the sacrificial layer at least through the one or more etch holes, and depositing a sealing layer over the cap layer and the one or more etch holes to encapsulate the one or more MEMS devices, the substrate, and the cap layer.

In a second aspect of the present invention, a device is disclosed, including: a substrate having one or more MEMS devices formed thereon, a cap layer, and a sealing layer, wherein the one or more MEMS devices are encapsulated within the cap layer and the sealing layer.

### BRIEF DESCRIPTION OF DRAWINGS

The accompanying figures, where like reference numerals refer to identical or functionally similar elements throughout the separate views and which together with the detailed description below are incorporated in and form part of the specification, serve to illustrate various embodiments and to explain various principles and advantages in accordance with a present embodiment.

FIG. 1 illustrates a side cross sectional perspective drawing of an encapsulated microelectromechanical system (MEMS) device produced by conventional Thin Film Encapsulation (TFE) techniques.

FIG. 2 illustrates a broad method of TFE in accordance with the present embodiment.

FIG. 3, comprising FIG. 3A to FIG. 3F, illustrates a side cross-sectional perspective drawings of a MEMS device undergoing TFE in accordance with the present embodiment.

FIG. 4, comprising FIG. 4A and FIG. 4B, illustrates an encapsulated MEMS device produced by TFE in accordance with the present embodiment, wherein FIG. 4A illustrates a top perspective drawing of the MEMS device and FIG. 4B illustrates a side cross-sectional perspective drawing of the MEMS device.

FIG. 5, comprising FIG. 5A and FIG. 5B, illustrates applications of encapsulated MEMS devices produced by TFE in accordance with the present embodiment, wherein FIG. 5A illustrates the encapsulated MEMS device applied as a cantilever resonator for radiofrequency (RF) applications, and FIG. 5B illustrates the encapsulated MEMS device as a tuneable capacitor.

Skilled artisans will appreciate that elements in the figures are illustrated for simplicity and clarity and have not necessarily been depicted to scale. For example, the dimensions of some of the elements in the block diagrams or flowcharts may be exaggerated in respect to other elements to help to improve understanding of the present embodiments.

### DETAILED DESCRIPTION

The following detailed description is merely exemplary in nature and is not intended to limit the invention or the application and uses of the invention. Furthermore, there is no intention to be bound by any theory, presented in the preceding background of the invention or the following detailed description. It is the intent of the present embodiment to present an improved method of thin film encapsulation (TFE) for fabrication of microelectromechanical system (MEMS) devices with embedded electrodes.

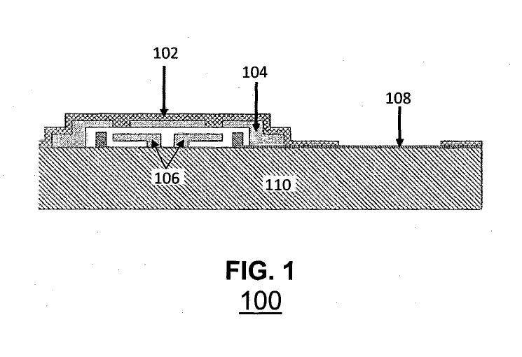

TFE is an attractive alternative technique to wafer bonding due to the possibility of reduced thickness and area of a packaged device, as well as low cost from elimination of a capping wafer. Conventional TFE techniques use deposition, etching, and release steps of surface micromachining approach of MEMS fabrication for packaging of a MEMS device. FIG. 1 illustrates a side cross sectional perspective drawing 100 of an encapsulated MEMS device produced using conventional TFE techniques. A cap layer 104 is deposited over a substrate 110 having one or more MEMS devices 106. A sealing layer 102 is deposited over the cap layer 104 to encapsulate the MEMS device 106. Conventional TFE methods producing encapsulated MEMS devices as in FIG. 1 suffers with issues such as a large footprint after TFE, large area occupation by signal routing 108, and padding and exposure of electrodes. Furthermore, if metal signal routings 108 are used, it would place limitations on the choice of capping material 104 because a metal cap layer 104 may cause an electrical shortage of signal lines 108. The metal single routings 108 would need to be isolated if a metal cap layer 104 is to be used. This increases the complexity in the fabrication process of TFE. Furthermore, metal signal routing lines 108 increases the possibility of delamination of the encapsulation at those places and may defeat the purpose of TFE due to leakage.

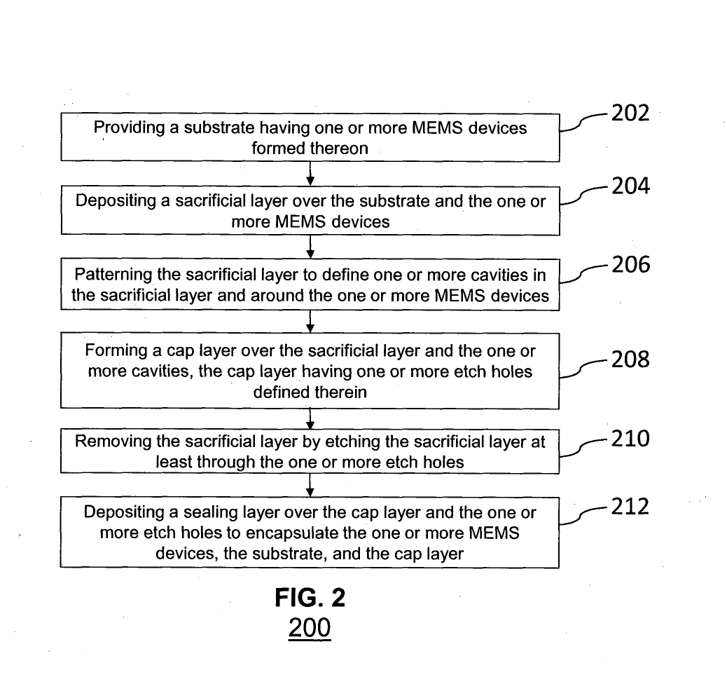

In order to improve the robustness of TFE against the above issues, a method of TFE for fabricating electrodes which are embedded in the encapsulation layer is disclosed below. FIG. 2 illustrates a broad method 200 of TFE in accordance with the present embodiment. In step 202, a substrate having one or more MEMS devices formed thereon is provided. In step 204, a sacrificial layer is deposited over the substrate and the one or more MEMS devices. In step 206, the sacrificial layer is pattered to define one or more cavities in the sacrificial layer and around the one or more MEMS devices. In step 208, a cap layer is formed over the sacrificial layer and the one or more cavities, the cap layer having one or more etch holes defined therein. In step 210, the sacrificial layer is removed by etching the sacrificial layer at least through the one or more etch holes. In step 212, a sealing layer is deposited over the cap layer and the one or more etch holes to encapsulate the one or more MEMS devices, the substrate, and the cap layer.

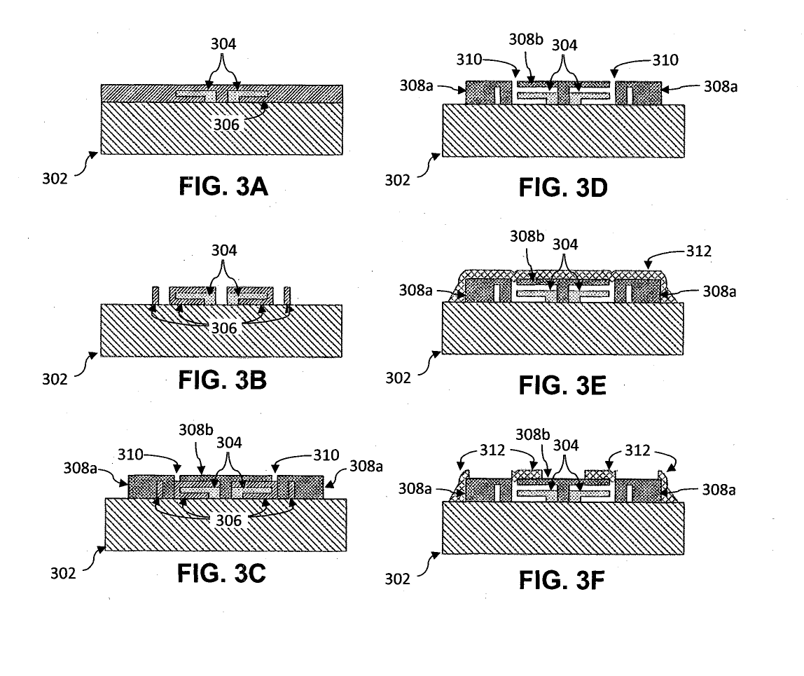

FIG. 3, comprising FIGS. 3A to 3F, illustrates a side cross-sectional perspective drawings of a MEMS device 304 undergoing TFE in accordance with the present embodiment. In FIG. 3A, the fabrication of encapsulated MEMS devices starts with providing a low resistivity silicon wafer substrate 302 having one or more MEMS devices 304 formed thereon. Preferably, the substrate 302 having one or more MEMS devices 304 formed thereon has been cleaned using integrated circuit (IC) fabrication cleaning techniques. A sacrificial layer 306 is deposited over the substrate 302 and the one or more MEMS devices 304 formed thereon. In an embodiment, a 3 micrometre (um) layer of PECVD oxide is deposited as a sacrificial layer 306. In an embodiment, the sacrificial layer comprises a dielectric material including plasma enhanced chemical vapour deposition (PECVD) oxide.

Subsequently, in FIG. 3B, the sacrificial layer 306 is patterned to define one or more cavities in the sacrificial layer 306 and around the one or more MEMS devices 304. The thickness of the sacrificial layer 306 defines the depth of cavity as the final depth of cavity will be decided later by the sealing process.

Next, in FIG. 3C, a cap layer 308a 308b, is formed over the sacrificial layer 306 and the one or more cavities, the cap layer 308a 308b having one or more etch holes 310 defined therein. This method is advantageous as the embedded electrodes are fabricated simultaneously during the formation of the metal cap layer 308a 308b.

In an embodiment, the step of forming the cap layer 308a 308b to define one or more etch holes 310 comprises electroplating the cap layer 308a 308b over the sacrificial layer 306 and the one or more cavities, laying a photoresist layer over the cap layer 308a 308b, patterning the photoresist layer, etching through the photoresist layer, and removing the photoresist layer. In an embodiment, Cu/Ti is deposited as a seed layer and a Ni cap layer 308a 308b is electroplated over the seed layer. The step of electroplating the Ni cap layer 308a 308b defines metal column structures and metal caps over the sacrificial layer 306.

Subsequently, in FIG. 3D, the sacrificial layer 306 is removed by etching the sacrificial layer 306 at least through the one or more etch holes 310. In an embodiment, the sacrificial layer 306 is removed by sacrificial oxide etching with vapour hydrofluoric acid (VHF) through the etch holes 310.

Next, in FIG. 3E; a sealing layer 312 is deposited over the cap layer 308a 308b and the one or more etch holes 310 to encapsulate the one or more MEMS devices 304, the substrate 302, and the cap layer 308a 308b. In a preferred embodiment, the etch holes 310 are sealed by 2 um thick PECVD oxide.

Finally, in FIG. 3F, the sealing layer 312 is patterned to expose portions of the cap layer 308a 308b for electrical contact after the depositing step. In an embodiment, the sealing layer 312 comprises a dielectric material including PECVD oxide.

This method advantageously makes the final encapsulated device small in size by reducing the size of electrical lines and electrical pads of the encapsulated MEMS devices. The capping layer can consist of several metal plates and column which are separated by dielectric layer to serve the purpose of electrodes and bond pads for apply the electrical field vertically and laterally to MEMS device. This method advantageously allows miniaturization of TFE packaged MEMS devices, providing for a reduction of the cost, time, and manufacturing complexity.

In an embodiment, the cap layer can also be used as an electrode to actuate MEMS device magnetically. These electrodes can be used for tuning the MEMS for Device for various applications like the frequency tuning in a radiofrequency (RF) device, for example, in a thin-film bulk acoustic resonator (FBAR) device by loading, or alternatively, in a variable capacitor by tuning the gap between the electrodes, changing the material properties of MEMS device material, or by introducing stress using applied force.

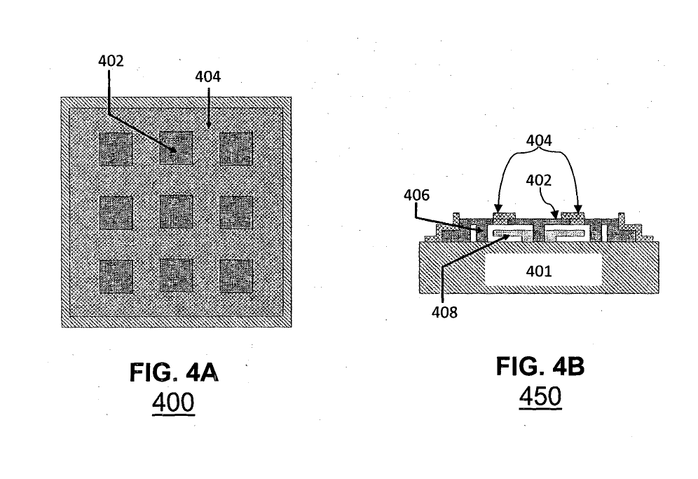

FIG. 4, comprising FIG. 4A and FIG. 4B, illustrates an encapsulated MEMS device produced by TFE in accordance with the present embodiment, wherein FIG. 4A illustrates a top perspective drawing 400 of the encapsulated MEMS device and FIG. 4B illustrates a side cross-sectional perspective drawing 450 of the encapsulated MEMS device.

The encapsulated MEMS device comprises a substrate having one or more MEMS devices formed thereon, a cap layer, and a sealing layer, wherein the one or more MEMS devices are encapsulated within the cap layer and the sealing layer.

In FIGS. 4A and 4B, the TFE comprises several columns 406 formed during the electroplating of the metal cap layer. Portions of the metal cap layer are isolated by a dielectric layer 404. These metal columns 406 of cap layer can serve as electrodes and bond pads for the application of electrical fields vertically and laterally.

Advantageously, these metal columns 406 (i.e. electrodes) can be used for tuning the MEMS devices 408. In order to apply an electrical field vertically to the MEMS device 408, part of the metal cap layer 402 isolated dielectrically can act as an electrode. Alternatively, to apply a lateral electrical field to MEMS device 408, metal columns 406 act as an electrode. Advantageously, these parts of metal caps 402 and columns 406 can be connected as desired for applying the electrical field for proper activation of the MEMS devices 408.

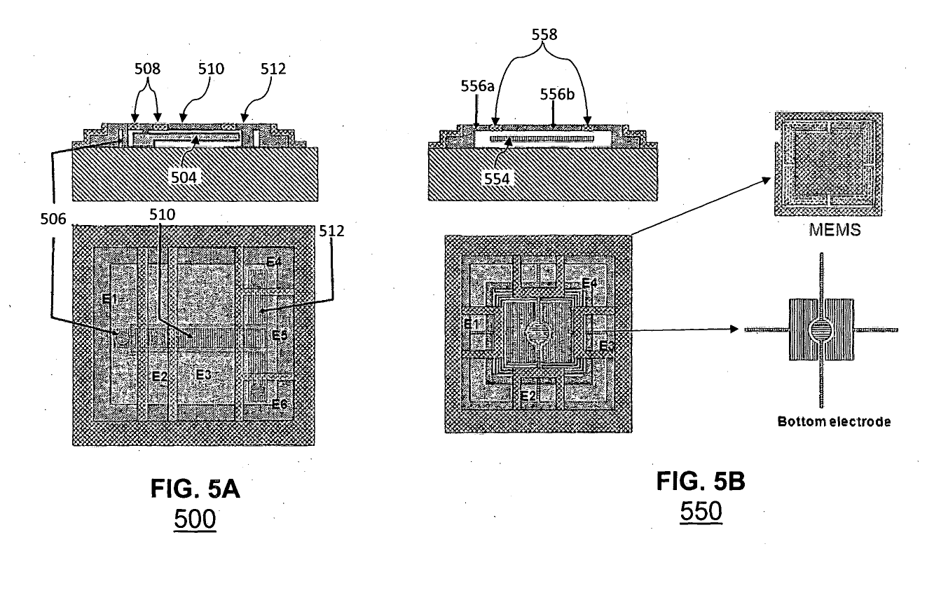

FIG. 5, comprising FIG. 5A and 5B, illustrates applications of encapsulated MEMS devices 504 554 produced by TFE in accordance with the present embodiment, wherein FIG. 5A illustrates the encapsulated MEMS device 504 applied as a cantilever resonator 500, and FIG. 5B illustrates the encapsulated MEMS device 554 applied as a tuneable capacitor 550.

FIG. 5A shows the cantilever resonator 500 for RF application comprising a MEMS device 504, top and bottom electrodes 510 512 and metal columns 506, wherein the metal columns are dielectrically isolated 508. The frequency of the cantilever resonator 504 can be tuned by applying force to cantilever 504 using E3 electrode 510.

FIG. 5B shows a variable capacitor 550 comprising a MEMS device 544, capping layer 556a, and an electrical pad 556b, the capping layer 556a and electrical pad 556b being dielectrically isolated 558. The gap between metal membrane 556b and bottom electrode (E2) can be tuned to change the capacitance by applying force to metal membrane 556a using E1 electrode.

The method in the present embodiment advantageously provides for an alternative means of TFE for realizing electrodes and pads which are embedded in the encapsulation layers to apply electrical field from top of cap layer for activating and tuning the encapsulated MEMS devices. The method of the present embodiment advantageously solves the main issue of large footprint of MEMS device after TFE by reducing long electrical lines and big electrical pads required adjacent to the cap layer for activating encapsulated MEMS devices. The method of the present embodiment advantageously solves the above issue by fabricating electrodes and pads simultaneously in the cap layer and isolating them with dielectric sealing layer. These embedded electrodes are used to apply the electrical force laterally and vertically to the MEMS devices. The cap layer can also be used as an electrode to actuate MEMS device magnetically. This advantageously simplifies the process of TFE as well as reduces occupying area of final MEMS devices after TFE and hence help in miniaturization of thin film packaged MEMS devices which further help in reduction of the cost, time and manufacturing complexity of TFE.

While exemplary embodiments have been presented in the foregoing detailed description of the invention, it should be appreciated that a vast number of variations exist.

It should further be appreciated that the exemplary embodiments are only examples, and are not intended to limit the scope, applicability, operation, or configuration of the invention in any way. Rather, the foregoing detailed description will provide those skilled in the art with a convenient road map for implementing an exemplary embodiment of the invention, it being understood that various changes may be made in the function and arrangement of elements and method of operation described in an exemplary embodiment without departing from the scope of the invention as set forth in the appended claims.

What is claimed is:

1. A method of fabricating encapsulated microelectromechanical system (MEMS) devices, comprising:
providing a substrate having one or more MEMS devices formed thereon;
depositing a sacrificial layer over the substrate and the one or more MEMS devices;
patterning the sacrificial layer to define one or more cavities in the sacrificial layer and around the one or more MEMS devices;
forming a cap layer over the sacrificial layer and the one or more cavities, the cap layer having one or more etch holes defined therein;
removing the sacrificial layer by etching the sacrificial layer at least through the one or more etch holes;
depositing a sealing layer over the cap layer and the one or more etch holes to encapsulate the one or more MEMS devices, the substrate, and the cap layer, and
patterning the sealing layer to expose a plurality of portions of the cap layer for electrical contact after the depositing step.

2. The method in accordance with claim 1, wherein the step of forming the cap layer to define one or more etch holes comprises:
electroplating the cap layer over the sacrificial layer and the one or more cavities;
laying a photoresist layer over the cap layer;
patterning the photoresist layer;
etching through the photoresist layer; and
removing the photoresist layer.

3. The method in accordance with claim 2, wherein the electroplating step comprises electroplating the cap layer to form a plurality of electrodes embedded in the encapsulated MEMS device.

4. The method in accordance with claim 2, wherein the step of electroplating comprises:
depositing a layer of Cu/Ti as a seed layer; and
electroplating an Ni cap layer over the seed layer.

5. The method in accordance with claim 1, wherein the substrate is a low resistivity silicon wafer.

6. The method in accordance with claim 1, wherein the sacrificial layer comprises a dielectric material including plasma enhanced chemical vapour deposition (PECVD) oxide.

7. The method in accordance with claim 1, wherein the sealing layer comprises a dielectric material including PECVD oxide.

8. The method in accordance with claim 7, wherein the one or more cavities patterned in the sacrificial layer and around the one or more MEMS devices define the cap layer to comprise a plurality of metal plates and metal columns, wherein the plurality of metal plates and metal columns are separated by the sealing layer to form a plurality of electrodes and bond pads embedded in the encapsulated MEMS device.

9. A device comprising:
a substrate;
one or more MEMS devices formed thereon;
a cap layer; and
a sealing layer;
wherein the one or more MEMS devices are encapsulated within the cap layer and the sealing layer, and
wherein the sealing layer is patterned to expose a plurality of portions of the cap layer for electrical contact.

10. The device in accordance with claim 9, wherein the cap layer comprises a plurality of electrodes embedded in the device.

11. The device in accordance with claim 9, wherein the cap layer comprises a plurality of metal plates and metal columns, wherein the plurality of metal plates and metal columns are separated by the sealing layer to form a plurality of electrodes and bond pads embedded in the device.

12. The device in accordance with claim 9, wherein the cap layer is configured to transmit electric fields vertically to the one or more MEMS devices encapsulated in response to the sealing layer providing dielectric isolation to predetermined segments of the cap layer.

13. The device in accordance with claim 9, wherein the cap layer is configured to transmit electric fields laterally to the one or more MEMS devices encapsulated in response to a corresponding metal column of the cap layer in contact with each of the one or more MEMS devices.

14. The device in accordance with claim 9, wherein the cap layer comprises a Ni cap layer electroplated on a Cu/Ti seed layer.

15. The device in accordance with claim 9, wherein the substrate is a low resistivity silicon wafer.

16. The device in accordance with claim 9, wherein the sealing layer comprises a dielectric material including PECVD oxide.
